(19) United States
(12) Patent Application Publication
(10) Pub. No.: US 2005/0104634 A1
(43) Pub. Date: May 19, 2005

(54) Frequency divider, PLL circuit and semiconductor integrated circuit

(76) Inventor: Minoru Fujishima, Kashiwa-shi (JP)

Correspondence Address: JOHN S. PRATT, ESQ;KILPATRICK STOCKTON, LLP, 1100 PEACHTREE STREET, ATLANTA, GA, 30309, US

(21) Appl. No.: 10/759,865

(22) Filed: Jan. 15, 2004

(30) Foreign Application Priority Data
Nov. 19, 2003 (JP) P2003-389652

(51) Int. Cl. H03B 19/00

(52) U.S. Cl. 327/117

(57) ABSTRACT

A frequency divider includes a first divider configured to divide an input signal, and to generate a first high-frequency signal. A second divider is configured to divide a second high-frequency signal, and to generate an output signal. A third divider is configured to generate a third high-frequency signal. A mixer is configured to execute arithmetic processing for the first and third high-frequency signals, and to generate the second high-frequency signal.

### BACKGROUND OF THE INVENTION

1. Field of the Invention

The present invention relates to a phase locked loop (PLL) circuit and, more particularly, to a frequency divider for the PLL circuit, and a semiconductor integrated circuit monolithically integrating the frequency divider on a single semiconductor chip.

2. Description of the Related Art

Mobile communication equipment using a considerable number of channels requires a highly accurate frequency generator. As a highly accurate frequency generator, a PLL frequency synthesizer using a PLL circuit of a pulse swallow system is known. The PLL circuit multiplies a low-frequency reference clock to generate a high-frequency signal. A voltage controlled oscillator (VCO) and a dual modulus divider connected to the VCO operate at the highest speed in the PLL circuit. The dual modulus divider is a type of a frequency divider. Additionally, the VCO oscillating at a frequency of about 50 [GHz] is provided. The dual modulus divider divides an oscillation frequency generated by the VCO. Therefore, the dual modulus divider must be operated at a higher speed in proportion to an increase in oscillation frequency of the VCO.

The PLL circuit of the pulse swallow system includes a dual modulus divider having two divider systems: a 1/N divider and a (1/N+1) divider (N: an integer of two or more). When the PLL circuit includes a frequency divider which cannot execute fractional dividing such as a pulse swallow system or the like, a frequency of the reference clock must be a common divisor of a frequency of an oscillation signal generated by the VCO.

For example, in a dual modulus divider including a ½ divider and a ⅓ divider, the ½ divider can be operated at a high speed because a delay generated during signal transmission is very small. On the other hand, the ⅓ divider cannot be operated at a high speed because the number of circuits of a signal path is large and delay time is large. Consequently, it is difficult to provide a frequency divider having an operating frequency equal to that of the VCO.

Moreover the frequency divider which cannot execute fractional dividing is normally designed by setting a reference clock frequency low. Accordingly, it is necessary to increase a time constant of a low-pass filter in a PLL circuit. In this case, not only set-up time is extended but also the size of a capacitor provided in the low-pass filter must be increased. Thus, integrating the PLL circuit on a semiconductor chip is difficult.

A divider has been developed having a desired division ratio by use a “switch system” for high-speed switching between the 1/N divider and the (1/N+1) divider. The switch system can be used when a frequency of a reference clock is high. The switch system executes high-speed switching between the 1/N divider and the (1/N+1) divider to effectively divide a frequency at a middle division ratio of the 1/N divider and the (1/N+1) divider. Consequently, switching noise is generated in the dual modulus divider employing the switch system. In order to remove the switching noise, design changes such as an increase in the order of the low-pass filter must be made, which will increase a circuit size and power consumption.

### SUMMARY OF THE INVENTION

An aspect of the present invention inheres in a frequency divider encompassing, a first divider configured to divide an input signal, and to generate a first high-frequency signal, a second divider configured to divide a second high-frequency signal, and to generate an output signal, a third divider configured to generate a third high-frequency signal, and a mixer configured to execute arithmetic processing for the first and third high-frequency signals, and to generate the second high-frequency signal.

Another aspect of the present invention inheres in a semiconductor integrated circuit encompassing, a first divider integrated on a semiconductor chip and configured to divide an input signal, and to generate a first high-frequency signal, a second divider integrated on the semiconductor chip and configured to divide a second high-frequency signal, and to generate an output signal, a third divider integrated on the semiconductor chip and configured to generate a third high-frequency signal, and a mixer integrated on the semiconductor chip and configured to execute arithmetic processing for the first and third high-frequency signals, and to generate the second high-frequency signal.

Still another aspect of the present invention inheres in a PLL circuit encompassing, a comparison oscillator configured to generate an oscillation signal having a frequency corresponding to a phase difference between a reference clock and a comparison clock, and a frequency divider configured to divide the oscillation signal to generate a first high-frequency signal, and to divide a second high-frequency signal, and to generate a third high-frequency signal, and to execute arithmetic processing for the first and third high-frequency signals and to generate the second high-frequency signal.

### BRIEF DESCRIPTION OF THE DRAWINGS

FIG. 1 is a block diagram showing a PLL circuit according to a first embodiment of the present invention;

FIG. 2 is a schematic diagram showing a configuration integrated the PLL circuit according to the first embodiment of the present invention monolithically on the single semiconductor chip;

FIG. 3 is a block diagram showing a PLL circuit according to a modification of the first embodiment of the present invention;

FIG. 4 is a block diagram showing a frequency divider according to a second embodiment of the present invention;

FIG. 5A is a circuit diagram showing a first ½ divider according to the second embodiment of the present invention;

FIG. 5B is a circuit diagram showing a third ½ divider according to the second embodiment of the present invention;

FIG. 6 is a circuit diagram showing a mixer according to the second embodiment of the present invention;

FIG. 7 is a block diagram showing a frequency divider according to a modification of the second embodiment of the present invention;

FIG. 8 is a circuit diagram showing a ½ divider according to the modification of the second embodiment of the present invention;

FIG. 9 is a block diagram showing a PLL circuit according to a third embodiment of the present invention;

FIG. 10 is a circuit diagram showing a mixer according to the third embodiment of the present invention;

FIG. 11 is a block diagram showing a PLL circuit according to a first modification of the third embodiment of the present invention;

FIG. 12 is a block diagram showing a PLL circuit according to a second modification of the third embodiment of the present invention;

FIG. 13 is a block diagram showing a frequency divider according to the second modification of the third embodiment of the present invention;

FIG. 14 is a block diagram showing a PLL circuit according to a third modification of the third embodiment of the present invention;

FIG. 15 is a block diagram showing a PLL circuit according to a fourth modification of the third embodiment of the present invention;

FIG. 16 is a block diagram showing a third divider according to the fourth modification of the third embodiment of the present invention; and

FIG. 17 is a block diagram showing a PLL circuit according to other embodiments of the present invention.

### DETAILED DESCRIPTION OF EMBODIMENTS

Various embodiments of the present invention will be described with reference to the accompanying drawings. It is to be noted that the same or similar reference numerals are applied to the same or similar parts and elements throughout the drawings, and description of the same or similar parts and elements will be omitted or simplified. In the following descriptions, numerous specific details are set forth such as specific signal values, etc. to provide a thorough understanding of the present invention. However, it will be obvious to those skilled in the art that the present invention may be practiced without such specific details. In other instances, well-known circuits have been shown in block diagram form in order not to obscure the present invention with unnecessary detail. In the following description, the words “connect” or “connected” defines a state in which first and second elements are electrically connected to each other without regard to whether or not there is a physical connection between the elements.

### First Embodiment

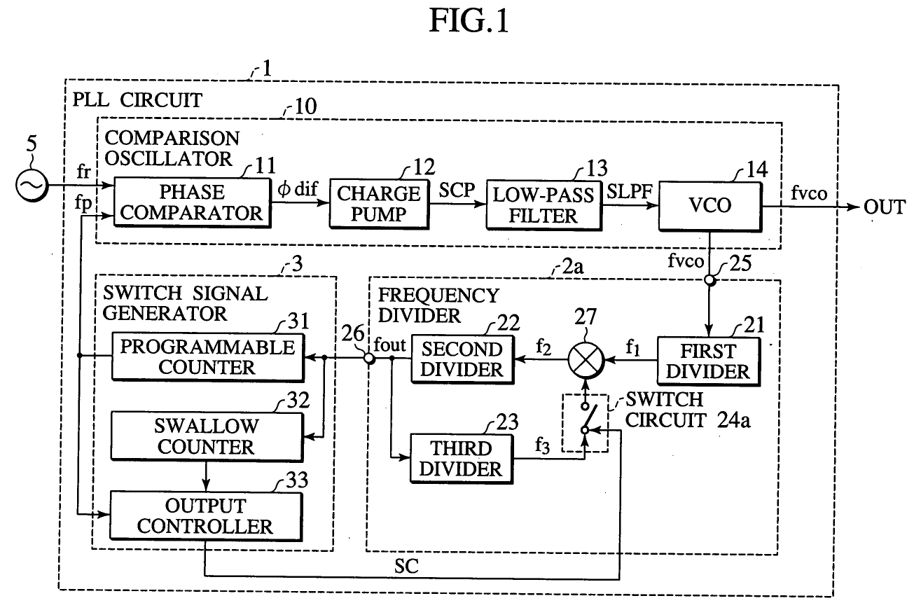

As shown in FIG. 1, a PLL circuit according to a first embodiment of the present invention includes a comparison oscillator 10 connected to a reference clock generator 5, a frequency divider 2a connected to the comparison oscillator 10, and a switch signal generator 3 connected between the frequency divider 2a and the comparison oscillator 10. The comparison oscillator 10 generates an oscillation signal f_{vco} having a frequency corresponding to a phase difference between the reference clock fr and a comparison clock fp. The frequency divider 2a divides the oscillation signal f_{vco} and generates a first high-frequency signal f₁. The frequency divider 2a divides a second high-frequency signal f₂, and generates a third high-frequency signal f₃. Additionally, the frequency divider 2a executes arithmetic processing for the first and third high-frequency signals f₁ and f₃, and generates the second high-frequency signal f₂.

The frequency divider 2a according to the first embodiment divides the oscillation signal f_{vco} by 1/a, 1/b and 1/c in sequence (where a, b, c are integers of 2 or higher). A frequency of the oscillation signal f_{vco} divided by 1/a and a frequency of the oscillation signal f_{vco} divided by 1/c are subtracted from each other. The oscillation signal f_{vco} divided by 1/b is generated as the output signal fₒᵤₜ. The frequency divider 2a judges or determines whether or not to subtract the oscillation signal f_{vco} divided by 1/a and the oscillation signal f_{vco} divided by 1/c from each other.

An oscillation signal f_{vco} generated by the comparison oscillator 10 is supplied to an input terminal 25 of the frequency divider 2a as an input signal. As shown in FIG. 1, the frequency divider 2a according to the first embodiment includes a first divider 21 connected to the input terminal 25, a mixer 27 connected to the first divider 21, a second divider 22 connected between the mixer 27 and an output terminal 26, and a third divider 23 connected between the output terminal 26 and the mixer 27.

The first divider 21, the second divider 22, and the third divider 23 have division ratios of 1/a, 1/b and 1/c, respectively. The mixer 27 generates a difference signal component between two input signals. The first divider 21 divides the input signal, and generates a first high-frequency signal f₁. The second divider 22 divides the second high-frequency signal f₂, and generates the output signal fₒᵤₜ. The third divider 23 generates the third high-frequency signal f₃. The mixer executes subtraction processing for the first and third high-frequency signals f₁ and f₃, and generates the second high-frequency signal f₂.

The frequency divider 2a further includes a switch circuit 24a connected between the mixer 27 and the third divider 23. The switch circuit 24a switches the connection between the mixer 27 and the third divider 23 in accordance with a switch signal SC. The switch signal generator 3 includes a programmable counter 31 and a swallow counter 32 connected to the output terminal 26, and an output controller 33 connected to the programmable counter 31 and the swallow counter 32. The output controller 33 selects an output signal of the programmable counter 31 or the swallow counter 32 as the switch signal SC.

The comparison oscillator 10 includes a phase comparator 11 having an input side connected to the reference clock generator 5 and the programmable counter 31, a charge pump 12 connected to an output side of the phase comparator 11, a low-pass filter (LPF) 13 connected to the charge pump 12, and a voltage controlled oscillator (VCO) 14 connected between the LPF 13 and the input terminal 25. The phase comparator 11 generates a phase difference signal φdif based on the phase difference between the reference clock fr generated by the reference clock generator 5 and the comparison clock fp generated by the programmable counter 31. The charge pump 12 generates a pulse output signal SCP having a pulse width corresponding to the phase difference signal φdif. The LPF 13 converts the pulse output signal SCP into a direct current (DC) voltage component, and generates a DC voltage SLPF. The VCO 14 oscillates at a frequency corresponding to the DC voltage SLPF, and generates the oscillation signal f_{vco}.

Next, an operation of the frequency divider 2a according to the first embodiment of the present invention will be described by referring of FIG. 1. The first divider 21 divides a frequency of the oscillation signal f_{vco} transmitted from the VCO 14 through the input terminal 25. Here, the following equation (1) is established:
f₁=f_{vco}/a (1)
where “f₁” is a frequency of the first high-frequency signal, “f_{vco}” is a frequency of the oscillation signal, and “1/a” is division ratio of the first divider 21. A second high-frequency signal f₂ generated by the mixer 27 is transmitted to the output terminal 26 through the second divider 22. The third divider 23 divides a frequency of the output signal fₒᵤₜ generated by the second divider 22. Here, the following equation (2) is established:
f₃=fₒᵤₜ/c (2)
where “f₃” is a frequency of the third high-frequency signal, “fₒᵤₜ” is a frequency of the output signal, and “1/c” is a division ratio of the third frequency divider 23. The mixer 27 executes subtraction processing for the first high-frequency signal f₁ and the third high-frequency signal f₃. Accordingly, when f_{vco}>fₒᵤₜ is set, the frequency f₂ is represented by the following equation (3):
f₂=f₁−f₃ (3)
where “f₂” is a frequency of the second high-frequency signal. When the equations (1) and (2) are substituted for the equation (3), the following equation (4) is established:
f₂=f_{vco}/a−fₒᵤₜ/c (4)

Here, when a division ratio of the second divider 22 is 1/b, a frequency of the output signal fₒᵤₜ is represented by the following equation (5):
fₒᵤₜ=(f_{vco}/a−fₒᵤₜ/c)/b (5)

When the equation (5) is solved for fₒᵤₜ, the following equation (6) is established:
fₒᵤₜ=f_{vco}/(ab+a/c) (6)

The output signal fₒᵤₜ is transmitted to the programmable counter 31 and the swallow counter 32 through the output terminal 26. When a=2, b=2, and c=4 are set in the equation (6), the following is established:
fₒᵤₜ=f_{vco}/4.5 (7)

On the other hand, when the switch circuit 24a is in an OFF state, c=0 is substituted in the equation (6) to establish the following equation (8):
fₒᵤₜ=f_{vco}/ab (8)

As is apparent from the equation (8), the oscillation signal f_{vco} is first divided by 1/a by the first divider 21, and then divided by 1/b by the second divider 22. For example, when a=2 and b=2 are set in the equation (8), the following equation (9) is established:
fₒᵤₜ=f_{vco}/4 (9)

As described above, according to the first embodiment, a desired division ratio can be obtained as indicated by the equation (7). Moreover, since the division ratio is set by arithmetic processing, no switching noise is generated. Furthermore, by using the first divider 21, the second divider 22, and the third divider 23 with a small delay time, high speed operation for the entire frequency divider 2a is achieved. Thus, by using the frequency divider 2a of the first embodiment for a PLL circuit 1, it is possible to provide the PLL circuit 1 which can be operated at a high frequency, such as at a millimeter waveband.

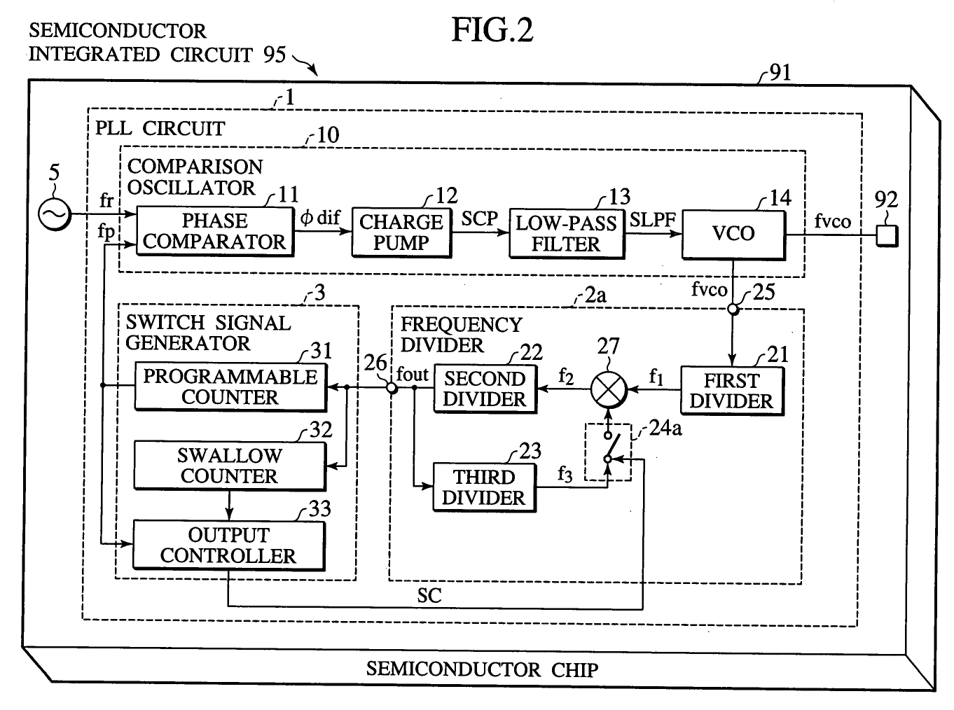

As shown in FIG. 2 for example, the reference clock generator 5, the comparison oscillator 10, the frequency divider 2a, and the switch signal generator 3 shown in FIG. 1 can be monolithically integrated on a single semiconductor chip 91, and a semiconductor integrated circuit 95 can be formed. In the example shown in FIG. 2, the semiconductor integrated circuit 95 further includes bonding pad 92 on the semiconductor chip 91. The bonding pad 92 is an internal terminal for transmitting the oscillation signal f_{vco} generated by the VCO 14 externally.

### Modification of First Embodiment

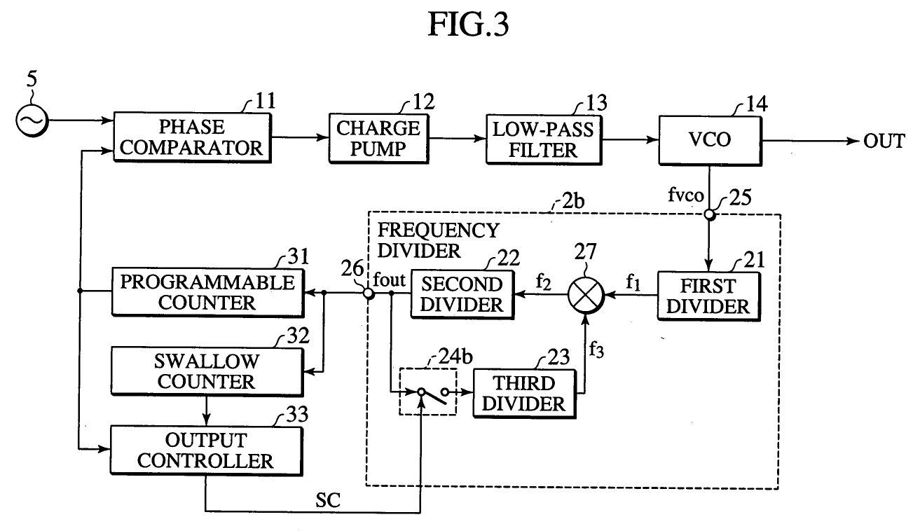

As a frequency divider 2b according to a modification of the first embodiment of the present invention, as shown in FIG. 3, a switch circuit 24b may be connected between the second divider 22 and the third divider 23. The switch circuit 24b shown in FIG. 3 switches connection between the second divider 22 and the third divider 23 in accordance with the switch signal SC. The frequency divider 2b shown in FIG. 3 is operated similarly to the frequency divider 2a shown in FIG. 1.

### Second Embodiment

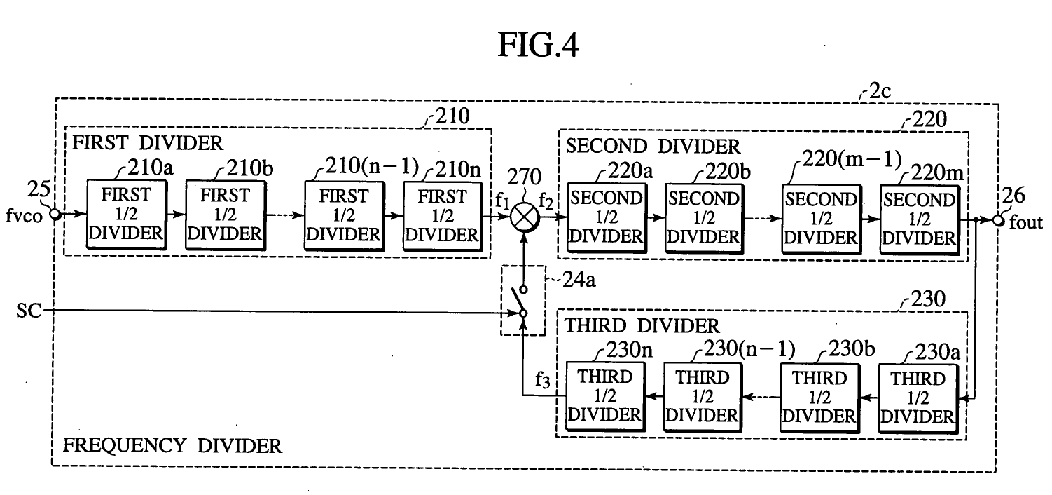

A frequency divider 2c shown in FIG. 4 is used as a part of the PLL circuit 1 shown in FIG. 1. As shown in FIG. 4, the frequency divider 2c according to a second embodiment of the present invention is different from the frequency divider 2a shown in FIG. 1 in that a first divider 210, a second divider 220 and a third divider 230, respectively, include a plurality of stages of cascade-connected first ½ dividers 210a to 210n, second ½ dividers 220a to 220m, and third ½ dividers 230a to 230n. Moreover, the number of stages of the first ½ dividers 210a to 210n and the number of stages of the third ½ dividers 230a to 230n are equal to each other. The frequency divider 2c shown in FIG. 4 can be monolithically integrated so as to form a semiconductor integrated circuit on a single semiconductor chip, the as same as FIG. 2.

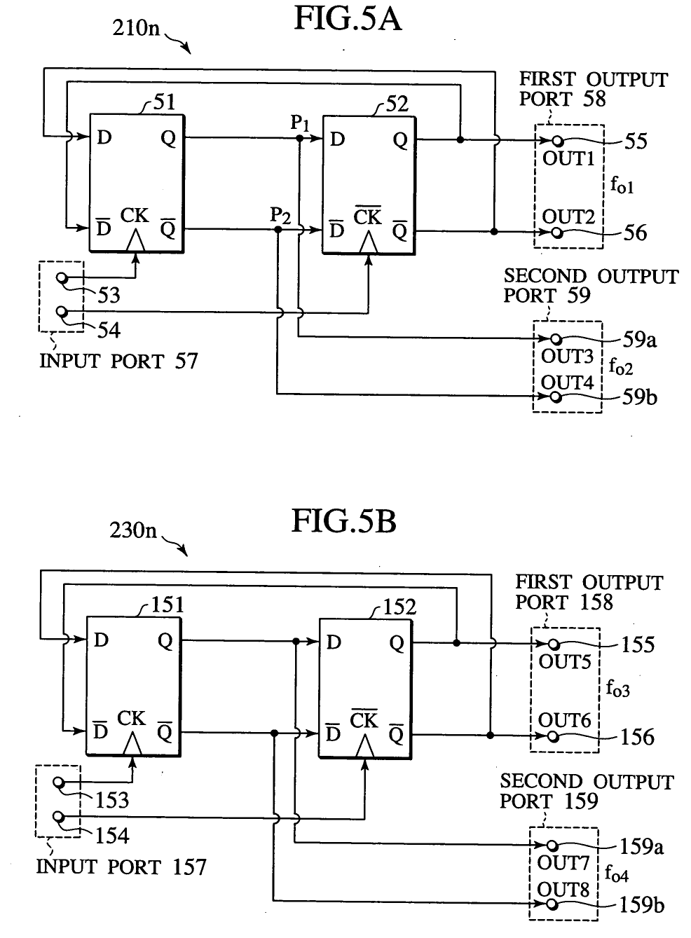

Each of the first ½ dividers 210a to 210n, the second ½ dividers 220a to 220m, and the third ½ dividers 230a to 230n shown in FIG. 4 includes a first latch circuit 51 and a second latch circuit 52 as shown in FIG. 5A. In FIG. 5A, the first ½ divider 210n of the last stage of the first divider 210 shown in FIG. 4 is shown as an example. The first latch circuit 51 has a clock input terminal CK connected to a first input terminal 53, a data input terminal D connected to a second output terminal 56, and an inversion data input terminal Dbar connected to a first output terminal 55. The second latch circuit 52 has an inversion clock input terminal CKbar connected to a second input terminal 54, a data input terminal D connected to a data output terminal Q of the first latch circuit 51, an inversion data input terminal Dbar connected to a inversion data output terminal Qbar of the first latch circuit 51, a data output terminal Q connected to the first output terminal 55, and an inversion data output terminal Qbar connected to the second output terminal 56. The first input terminal 53 and the second input terminal 54 constitute an input port 57. The first output terminal 55 and the second output terminal 56 constitute a first output port 58.

Output clocks of the first ½ divider 210(n−1) shown in FIG. 4 are supplied to the clock input terminal CK of the first latch circuit 51 and the inversion clock input terminal CKbar of the second latch circuit 52. Note that the first ½ dividers 210(n−1) generate clock signals having phases opposite to each other. The first latch-circuit 51 functions as a master latch. On the other hand, the second latch circuit 52 functions as a slave latch. That is, a signal makes two rounds in the first latch circuit 51 and the second latch circuit 52. As a result, output signals OUT1, OUT2 obtained by doubling a cycle of an input signal supplied through the input port 57, i.e., dividing a frequency by ½, are generated from the first output port 58.

A third output terminal 59a is connected to a connection node P1 of the first latch circuit 51 and the second latch circuit 52. A fourth output terminal 59b is connected to a connection node P2 of the first latch circuit 51 and the second latch circuit 52. The third output terminal 59a and the fourth output terminal 59b constitute a second output port 59. Note that no second output ports 59 of FIGS. 5A and 5B are provided in the first ½ dividers 210a to 210(n-1) of the stages before the first ½ divider 210n shown in FIG. 5A. Further, the third ½ divider 230n shown in FIG. 5B is constituted similarly to the first ½ divider 210n shown in FIG. 5A.

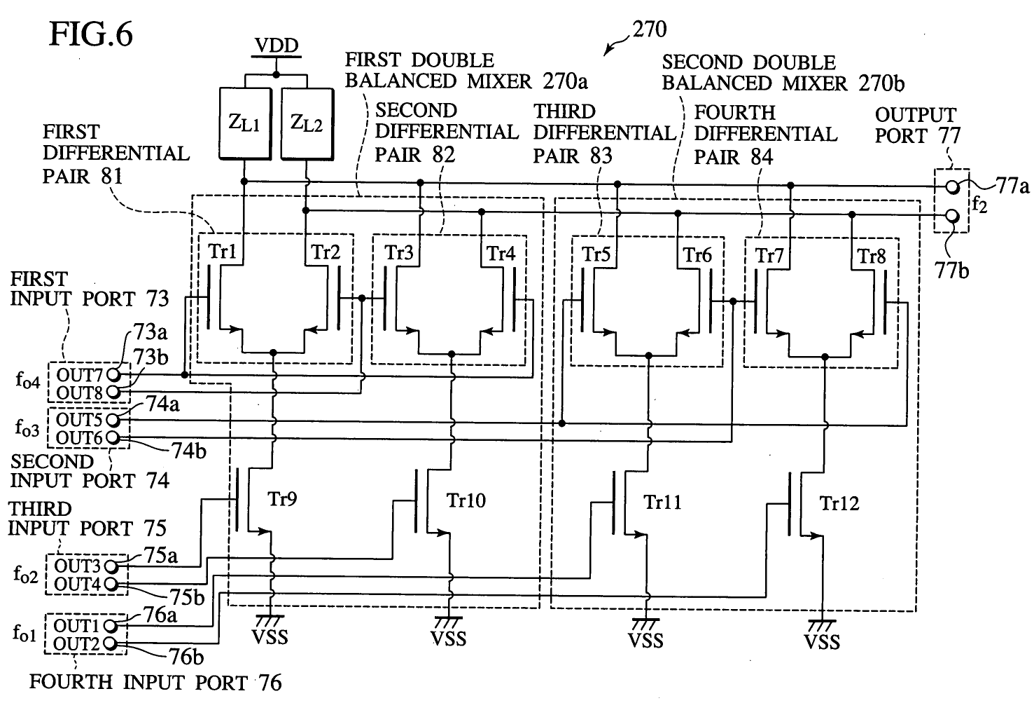

As shown in FIG. 6, the mixer 270 includes a first load resistance ZL1 and a second load resistance ZL2 connected to a power source VDD, a first double balanced mixer 270a connected to a first input port 73 and a third input port 75, and a second double balanced mixer 270b connected to a second input port 74 and a fourth input port 76. The fourth input port 76 is connected to the first output port 58 of the first ½ divider 210n shown in FIG. 5A. The third input port 75 is connected to the second output port 59 of the first ½ divider 210n. The second input port 74 is connected to the first output port 158 of third ½ divider 230n shown in FIG. 5B. The first input port 73 is connected to the second output port 159 of the third ½ divider 230n.

The first double balanced mixer 270a includes a first differential pair 81, a second differential pair 82, a first current source transistor Tr9, and a second current source transistor Tr10. The first current source transistor Tr9 has a drain connected to the first differential pair 81, a gate connected to the third input port 75, and a source connected to a ground VSS. The second current source transistor Tr10 has a drain connected to the second differential pair 82, a gate connected to the third input port 75, and a source connected to a ground VSS. The first differential pair 81 includes first and second differential transistors Tr1 and Tr2 having drains connected to the output port 77, gates connected to the first input port 73, and sources connected to the drain of the first current source transistor Tr9. The second differential pair 82 includes third and fourth differential transistors Tr3 and Tr4 having drains connected to the output port 77, gates connected to the first input port 73, and sources connected to the drain of the second current source transistor Tr10.

On the other hand, the second double balanced mixer 270b includes a third differential pair 83, a fourth differential pair 84, a third current source transistor Tr11, and a fourth current source transistor Tr12. The third current source transistor Tr1 has a drain connected to the third differential pair 83, a gate connected to the fourth input port 76, and a source connected to the ground VSS. The fourth current source transistor Tr12 has a drain connected to the fourth differential pair 84, a gate connected to the fourth input port 76, and a source connected to the ground VSS. The third differential pair 83 includes fifth and sixth differential transistors Tr5 and Tr6 having drains connected to the output port 77, gates connected to the second input port 74, and sources connected to the drain of the third current source transistor Tr11. The fourth differential pair 84 includes seventh and eighth differential transistors Tr7 and Tr8 having drains connected to the output port 77, gates connected to the second input port 74, and sources connected to the drain of the fourth current source transistor Tr12. An n-channel metal-oxide-semiconductor (nMOS) transistor can be used as the first to fourth current source transistors Tr9 to Tr12, and the first to eighth differential transistors Tr1 to Tr8.

A first high-frequency signal f₁ and a third high-frequency signal f₃ are supplied to the mixer 270. The first double balanced mixer 270a executes an analog arithmetic operation to multiply a second divided signal fₒ₂ by a fourth divided signal fₒ₄. On the other hand, the second double balanced mixer 270b executes an analog arithmetic operation to multiply a first divided signal fₒ₁ by a third divided signal fₒ₃. As a result, an output signal f₂ of the mixer 270 is represented by the following equation (10):
f₂=fₒ₁×fₒ₃+fₒ₂×fₒ₄ (10)

A phase of the first divided signal fₒ₁ and a phase of the second divide signal fₒ₂ of FIG. 5A are shifted from each other by 90°. Similarly, a phase of the third divided signal f₀₃ and a phase of the fourth divided signal fₒ₄ of FIG. 5B are shifted from each other by 90°. Thus, if the first divided signal fₒ₁ is set to “cosω₁”, the second divided signal fₒ₂ to “sinω₁”, the third divided signal f₀₃ to “cosω₂”, and the fourth divided signal fₒ₄ to “sinω₂”, according to the equation (10), the output signal f₂ of the mixer 270 is represented by the following equation (11):

$$\begin{matrix}{f}_{2} = cos {ω}_{1} \times cos {ω}_{2} + sin {ω}_{1} \times sin {ω}_{2} \\ = cos ( {ω}_{1} - {ω}_{2} )\end{matrix} \qquad ( 11 )$$

As apparent from the equation (11), the mixer 270 extracts only a difference signal component of a frequency.

Next, an operation of the frequency divide 2c according to the second embodiment of the present invention will be described by use of FIGS. 4 to 6. Repeated descriptions for the same operations according to the second embodiment which are the same as the first embodiment of the present invention are omitted. The first divider 210 shown in FIG. 4 divides a frequency of an oscillation signal f_{vco} transmitted from the VCO 14 of FIG. 1 through the input terminal 25. Here, if a division ratio of the first divider 210 is “½ⁿ”, a frequency of a first high-frequency signal f₁ is represented by the following equation (12):
f₁=f_{vco}/2ⁿ (12)

The third divider 230 divides an output signal fₒᵤₜ. Here, if a division ratio of the third divider 230 is “½ⁿ”, a frequency of a third high-frequency signal f₃ is represented by the following equation (13):
f₃=fₒᵤₜ/2ⁿ (13)

Thus, in the case of f_{vco}>fₒᵤₜ, a frequency of a second high-frequency signal f₂ is represented by the following equation (14):
f₂=(f_{vco}−fₒᵤₜ)/2ⁿ (14)

The second high-frequency signal f₂ is further divided to “½^{m}” by the second divider 220. As a result, an output signal fₒᵤₜ is represented by the following equation (15):

$$\begin{matrix}{f}_{out} = ( ( {f}_{vco} - {f}_{out} ) / {2}^{n} ) / {2}^{m} \\ = ( {f}_{vco} - {f}_{out} ) {2}^{n + m}\end{matrix} \qquad ( 15 )$$

If the equation (15) is solved for fₒᵤₜ, the following equation is established (16):
fₒᵤₜ=f_{vco}/(2^{n+m}+1) (16)

On the other hand, if the switch circuit 24a is in an OFF state, a frequency of an output signal fₒᵤₜ of the frequency divider 2c is represented by the following equation (17):
fₒᵤₜ=f_{vco}/2^{n+m} (17)

Thus, according to the second embodiment, the frequency divider 2c is constituted so as to have a small in delay time and operable at a high speed by providing the first ½ dividers 210a to 210n, the second ½ dividers 220a to 220m and the third ½ dividers 230a to 230n respectively in the first divider 210, the second divider 220 and the third divider 230. Moreover, switching noise is not generated, as in the case of the frequency divider 2a shown in FIG. 1.

### Modification of Second Embodiment

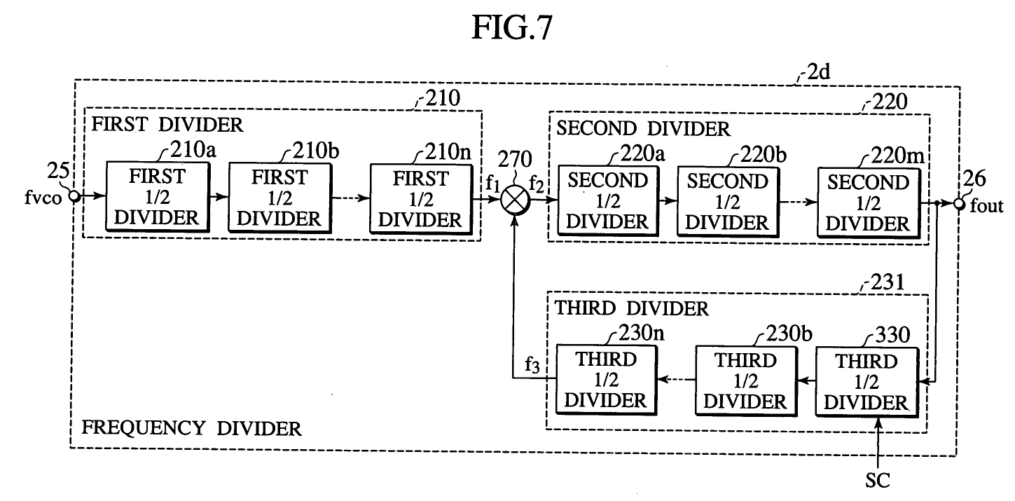

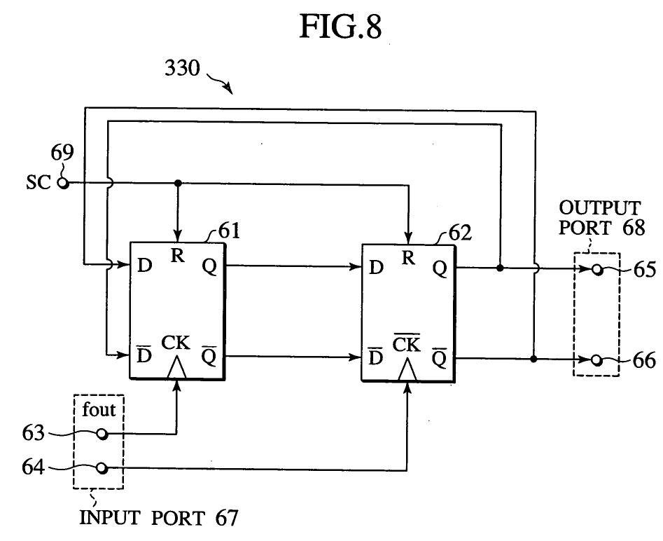

As a frequency divider 2d of a modification of the second embodiment of the present invention, as shown in FIG. 7, a switch signal SC may be supplied to a third ½ divider 330 of a third divider 231. As shown in FIG. 8, the third ½ divider 330 includes a first latch circuit 61 and a second latch circuit 62. The first latch circuit 61 has a reset terminal R connected to a switch signal terminal 69, a clock input terminal CK connected to a first input terminal 63, a data input terminal D connected to a second output terminal 66, and an inversion data input terminal Dbar connected to a first output terminal 65. The second latch circuit 62 has a reset terminal R connected to the switch signal terminal 69, an inversion clock input terminal CKbar connected to a second input terminal 64, a data input terminal D connected to a data output terminal Q of the first latch circuit 61, an inversion data input terminal Dbar connected to a inversion data output terminal Qbar of the first latch circuit 61, a data output terminal Q connected to the first output terminal 65, and an inversion data output terminal Qbar connected to the second output terminal 66.

The switch signal SC is transmitted through the switch signal terminal 69 to the reset terminals R of the first latch circuit 61 and the second latch circuit 62. The first latch circuit 61 and the second latch circuit 62 stop latching operations in accordance with the switch signal SC. As a result, the frequency divider 2d can be constituted to directly switch a division ratio based on the switch signal SC from the swallow counter 32 shown in FIG. 1. Thus, the switch circuit 24a shown in FIG. 1 becomes unnecessary.

### Third Embodiment

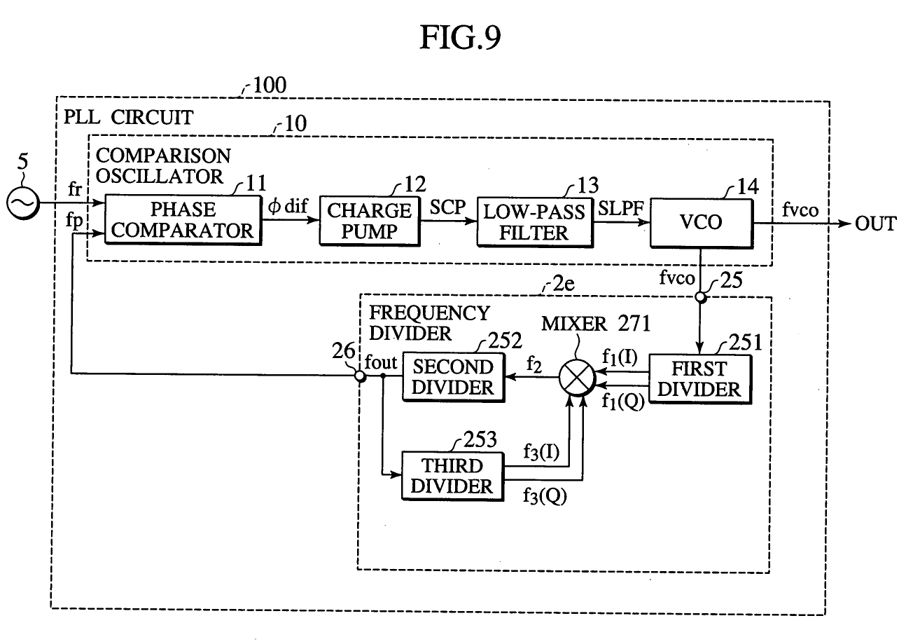

As shown in FIG. 9, a PLL circuit 100 of a third embodiment of the present invention is different from the PLL circuit 1 shown in FIG. 1 in that a switch signal generator 3 is not provided. Other configurations are similar to the PLL circuit shown in FIG. 1. The PLL circuit 100 shown in FIG. 9 can be monolithically integrated so as to form a semiconductor integrated circuit on a single semiconductor chip as same as FIG. 2.

Moreover, a frequency divider 2e shown in FIG. 9 is different from the frequency divider 2a shown in FIG. 1 in that division ratios of a second divider 252 and a third divider 253 are variable. That is, programmable dividers are used for the second divider 252 and the third divider 253. On the other hand, a division ratio of a first divider 251 is fixed. A maximum operating frequency of the programmable divider is generally low compared with that of a division ratio non-variable divider. Thus, operating frequencies of the second divider 252 and the third divider 253 are lower than that of the first divider 251. The division ratios of the second divider 252 and the third divider 253 are programmed so that the switch signal generator 3 and the switch circuit 24a shown in FIG. 1 are unnecessary.

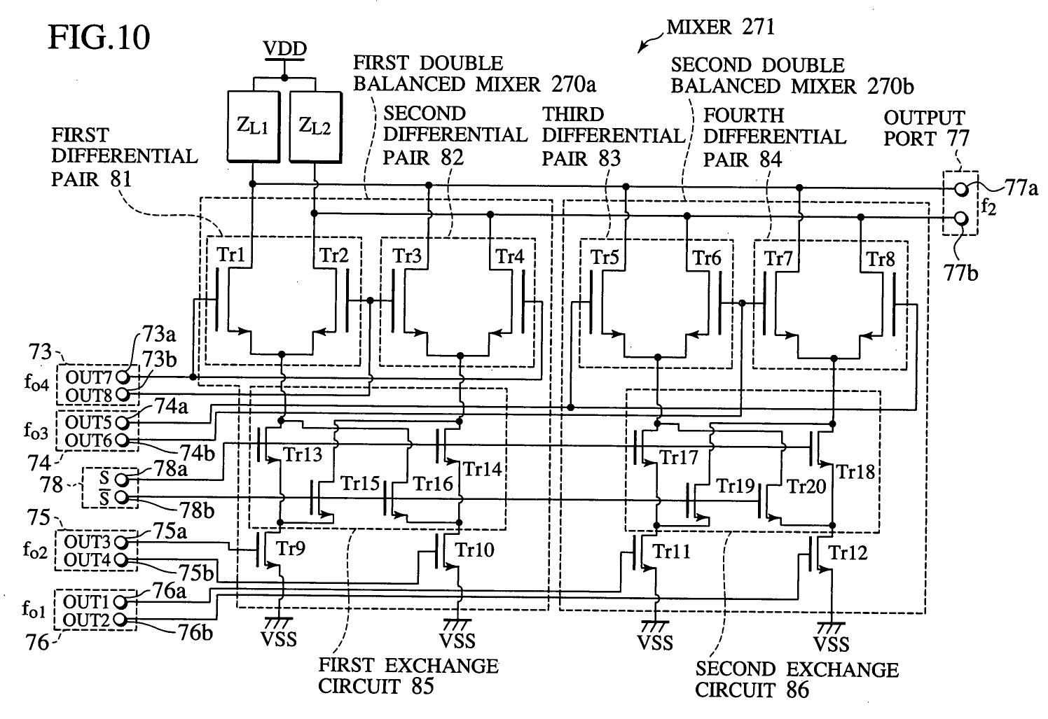

Additionally, the frequency divider 2e is different from the frequency divider 2a shown in FIG. 1 in that a mixer 271 can execute not only subtraction processing but also addition processing. As shown in FIG. 10, the mixer 271 further includes a first exchange circuit 85 and a second exchange circuit 86. The first exchange circuit 85 is connected between the first and second differential pairs 81 and 82 and the first and second current source transistors Tr9 and Tr10. The second exchange circuit 86 is connected between the third and fourth differential pairs 83 and 84 and the third and fourth current source transistors Tr11 and Tr12. Exchange signals S and Sbar are supplied from the outside to the fifth input port 78. The first exchange circuit 85 exchanges connections between the first differential pair 81 and the second differential pair 82 and between the first current source transistor Tr9 and the second current source transistor Tr10 based on the exchange signals S and Sbar. The second exchange circuit 86 exchanges connections between the third differential pair 83 and the fourth differential pair 84 and between the third current source transistor Tr11 and the fourth current source transistor Tr12 based on the exchange signals S and Sbar. As a result, the mixer 271 can switch a subtraction operation and an addition operation in accordance with the exchange signal S. The exchange signal S is supplied by, for example, the external central processing unit (CPU) of the PLL circuit 100 shown in FIG. 9. Alternatively, if a sigma/delta (ΣΔ) modulated digital signal is supplied to the PLL circuit 100, a ΣΔ modulator supplies the exchange signals S and Sbar.

Next, an operation of the frequency divide 2e according to the third embodiment of the present invention will be described by use of FIG. 9. Repeated descriptions for the same operations according to the second embodiment which are the same as the first embodiment of the present invention are omitted. A frequency of a first high-frequency signal f₁ generated by the first divider 251 is represented by the following equation (18) similar to the equation (1):
f₁=f_{vco}/a (18)

A frequency of a third high-frequency signal f₃ generated by the third divider 253 is represented by the following equation (19) similarly to the equation (2):
f₃=fₒᵤₜ/c (19)

The mixer 271 executes subtraction processing or addition processing for the first high-frequency signal f₁ generated by the first divider 251 and the third high-frequency signal f₃ generated by the third divider 253. Accordingly, in the case of f_{vco}>fₒᵤₜ, a frequency f₂ of an output signal of the mixer 271 is represented by the following equation (20):
f₂=f₁±f₃ (20)

When the equations (18) and (19) are substituted for the equation (20), the following equation (21) is established:
f₂=f_{vco}/a±fₒᵤₜ/c (21)

Here, when a division ratio of the second divider 252 is 1/b, a frequency of an output signal fₒᵤₜ supplied from the second divider 252 is represented by the following equation (22):
fₒᵤₜ=(fₒᵤₜ/a±fₒᵤₜ/c)/b (22)

When the equation (22) is solved for fₒᵤₜ, the following equation (23) is established:
fₒᵤₜ=f_{vco}/(ab±a/c) (23)

For example, if a=4, b=variable, c=x, 2, 4 are set in the equation (23) (x: fixed so that an output of the third divider 253 can be constant), the following equation is established:
fₒᵤₜ=f_{vco}/(4b±{0, 1, 2}) (24)

From the equation (24), in the case of b=1, the frequency divider 2e has division ratios of 1/2, 1/3, 1/4, 1/5, . . . . In the case of b=2, the frequency divider 2e has division ratios of 1/6, in, 1/8, 1/9, . . . .

Thus, according to the third embodiment, by using the programmable divider for one or both of the second divider 252 and the third divider 253, and having the mixer 271 execute the addition processing, the frequency divider 2e can be constituted to obtain a desired division ratio. Moreover, the switch signal generator 3 shown in FIG. 1 becomes unnecessary.

### First Modification of Third Embodiment

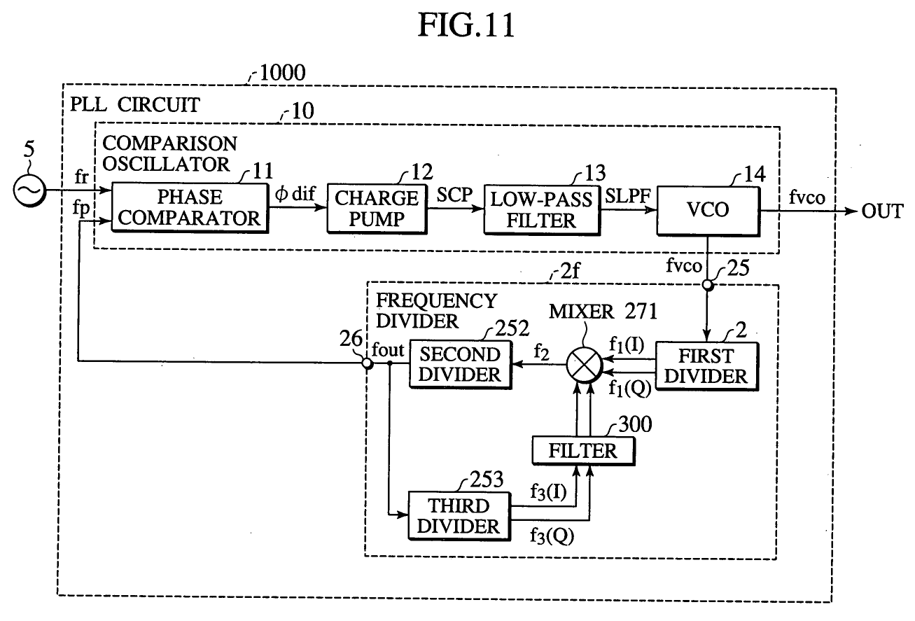

According to a first modification of the third embodiment of the present invention, as shown in FIG. 11, a frequency divider 2f of a PLL circuit 1000 may further include a filter 300 connected between the third divider 253 and the mixer 271. For example, a polyphase filter can be used for the filter 300. The filter 300 removes a higher harmonic wave component from the third high-frequency signal f₃.

When a digital circuit is used for the third divider 253 of FIG. 9, the third high-frequency signal f₃ has a signal shape similar to a square wave. However, not only the fundamental wave, but also many higher harmonic waves are contained in the third high-frequency signal f₃. Thus, in the mixer 271, arithmetic processing is executed not only for the fundamental wave but also for the higher harmonic wave components. As a result, a second high-frequency signal f₂ generated by the mixer 271 contains many spurious components around a desired frequency band. For example, when division ratios of the first, second and third dividers 251, 252 and 253 are respectively 1/2, 1/4 and 1/2, and an oscillation signal f_{vco} is 9[GHz], a first high-frequency signal f₁=4.5 [GHz], a second high-frequency signal f₂₌₄ [GHz], a third high-frequency signal f₃=0.5 [GHz], and an output signal fₒᵤₜ=1 [GHz] are set. Here, when the third high-frequency signal f₃ contains a higher harmonic wave, an output signal fₒᵤₜ=1.5, 2, . . . [GHz] is set. Then, frequencies of the second high-frequency signal f₂=4, 3.5, 3 . . . [GHz] are generated. In the case of the signal f₂, a spurious component appears at 3.5 [GHz] which is very close to a desired frequency 4 [GHz]. The higher harmonic wave of the signal f₃ must be removed in order to remove this spurious component.

Note that when the polyphase filter is used for the filter 300, different processing operations are executed for negative and positive frequencies of f₃(I) equivalent to a real number signal and f₃(Q) equivalent to an imaginary number signal. That is, only the negative frequency is removed while the positive frequency is directly passed. Thus, it is possible to effectively remove a third higher harmonic wave which is strongly contained in the digital signal, similar to a square wave. As a result, it is possible to selectively take out only a positive signal component of the third high-frequency signal f₃ generated by the third divider 253.

### Second Modification of Third Embodiment

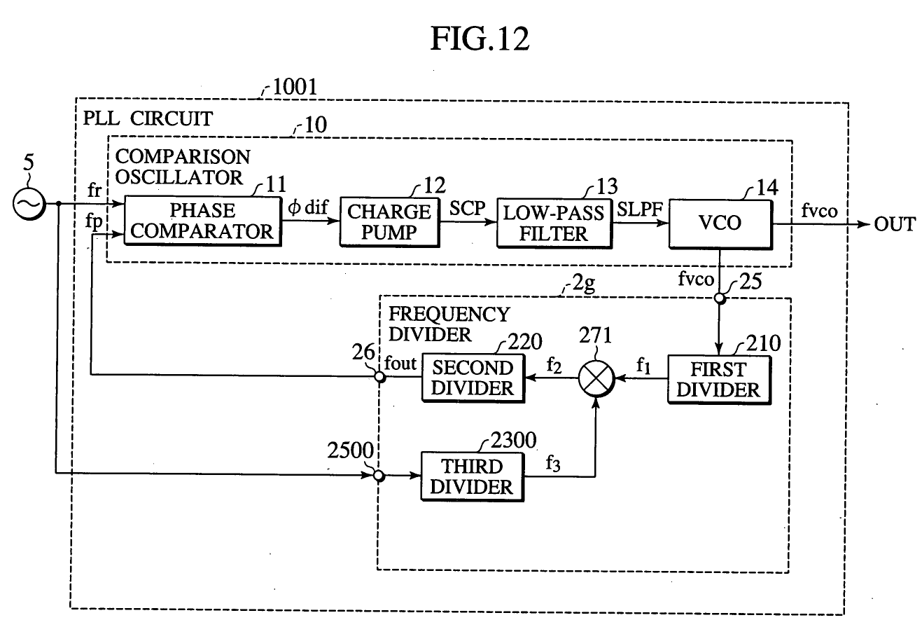

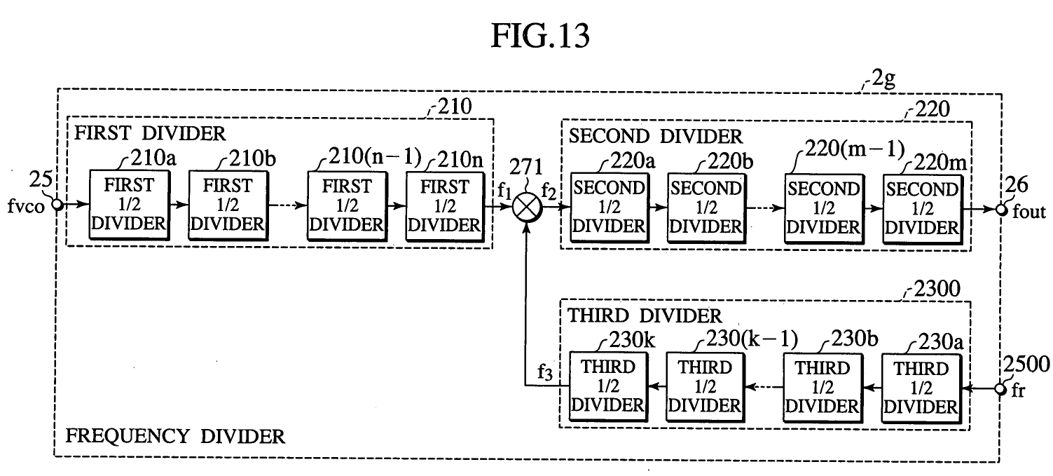

As a PLL circuit 1001 of a second modification of the third embodiment of the present invention, as shown in FIG. 12, an arrangement may be employed in which a reference clock fr is supplied to a third divider 2300 in place of the output signal fₒᵤₜ. A mixer 271 is similar to that of FIG. 10. That is, the mixer 271 can execute both addition processing and subtraction processing. As shown in FIG. 13, the third divider 2300 includes third ½ dividers 230a to 230k (k: integer of 2 or higher). A reference clock input terminal 2500 is connected to an input of the third divider 230a of a first stage. The mixer 271 is connected to an output of the third divider 230k of a last stage. On the other hand, first and second dividers 210 and 220 are similar to those of FIG. 4.

Each of the foregoing frequency dividers 2a to 2f feeds back the oscillation signal f_{vco} divided by the plurality of dividers to generate the third high-frequency signal f₃. In this case, there is a possibility that a long time is required for the frequency of the third high-frequency signal f₃ to become stable. There is a possibility that vibration will occur without stabilization of the frequency of the third high-frequency signal f₃.

On the other hand, a frequency divider 2g of the second modification of the third embodiment can stably generate a third high-frequency signal f₃ since it generates the third high-frequency signal f₃ based on the reference clock fr in place of the oscillation signal f_{vco}. Thus, it is possible to provide a the frequency divider 2g which can stably generate an optional division ratio that is not limited to an integer. Moreover, since each of the first, second and third dividers 210, 220 and 2300 is constituted by multistage connection of the ½ dividers, it is possible to provide a frequency divider 2g and PLL circuit 1001 which are operable at a high speed and with low power consumption.

### Third Modification of Third Embodiment

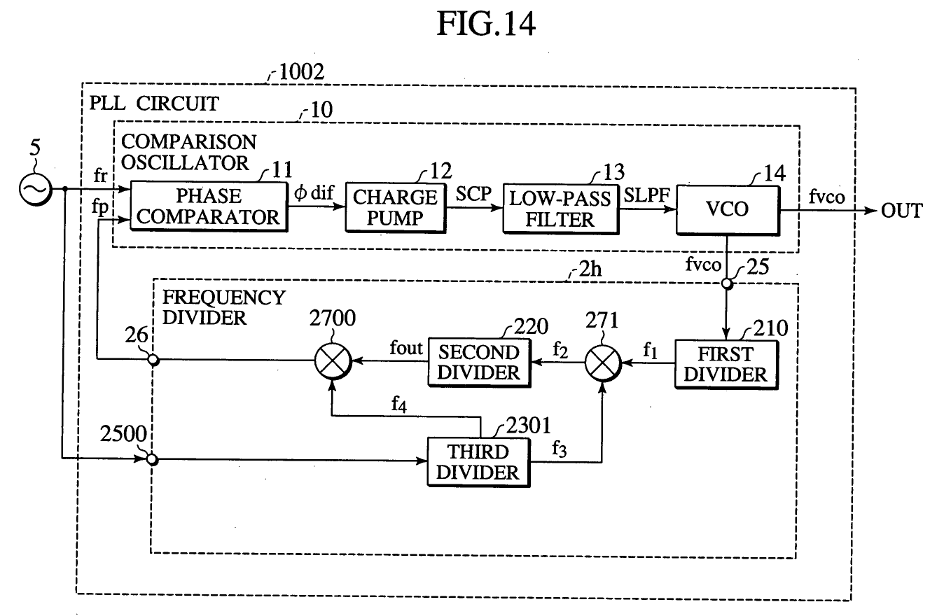

As shown in FIG. 14, a frequency divider 2h of a third modification of the third embodiment of the present invention may include, in addition to the components of FIG. 12, a first output mixer 2700 connected to the output sides of the second divider 220 and the third divider 2301 on the input side thereof, and connected to the output terminal 26 on the output side thereof. The first output mixer 2700 is constituted similar to, e.g., that of FIG. 6. That is, the first output mixer 2700 is constituted so as to be able to execute only subtraction processing. Moreover, the third divider 2301 supplies a fourth high-frequency signal f₄ to the first output mixer 2700.

For example, in an electronic toll collection (ETC) system, frequencies of 5795 [MHz], 5805 [MHz], 5835 [MHz], and 5845 [MHz] are necessary. That is, in the case of applying a PLL circuit 1002 to the ETC system, the VCO 14 oscillates at one of the frequencies 5795 [MHz], 5805 [MHz], 5835 [MHz], and 5845 [MHz] in accordance with a channel. Here, when division ratios of the first and second divides 210 and 220 are 1/4, a first high-frequency signal f₁ is set to one of the frequencies 1468.25 [MHz], 1458.75 [MHz], 1451.25 [MHz], and 1448.75 [MHz]. A frequency of the reference clock fr is set to 360 [MHz].

The third divider 2301 divides the reference clock fr by 1/288 to generate a third high-frequency signal f₃ which has a frequency of 1.25 [MHz]. The mixer 271 executes subtraction processing for the first high-frequency signal f₁ and the third high-frequency signal f₃ when a frequency of the first high-frequency signal f₁ is 1468.25 [MHz]. As a result, a frequency of a second high-frequency signal f₂ becomes 1460 [MHz]. On the other hand, the mixer 271 executes addition processing for the first high-frequency signal f₁ and the third frequency signal f₃ when a frequency of the first high-frequency signal f₁ is 1458.75 [MHz]. Accordingly, a frequency of the second high-frequency signal f₂ becomes 1460 [MHz]. Note that switching between the addition processing and the subtraction processing in the mixer 271 is controlled based on, e.g., the exchange signals S and Sbar shown in FIG. 10.

The mixer 271 executes subtraction processing for the first high-frequency signal f₁ and the third high-frequency signal f₃ when a frequency of the first high-frequency signal f₁ is 1451.25 [MHz]. Thus, a frequency of the second high-frequency signal f₂ becomes 1450 [MHz]. Additionally, the mixer 271 executes addition processing for the first high-frequency signal f₁ and the third high-frequency signal f₃ when a frequency of the first high-frequency signal f₁ is 1448.75 [MHz]. In this case, a frequency of the second high-frequency signal f₂ becomes 1450 [MHz]. Thus, the frequency of the second high-frequency signal f₂ becomes one of 1460 [MHz] and 1450 [MHz]. The second divider 220 divides the second high-frequency signal f₂ by 1/4 to generate an output signal fₒᵤₜ which has one of the frequencies 365 [MHz] and 362.5 [MHz].

On the other hand, the third divider 2301 sets a frequency of the fourth high-frequency signal f₄ to, e.g., one of 5 [MHz] and 2.5 [MHz] in accordance with a channel. When a frequency of the reference clock fr is 360 [MHz], the third divider 2301 divides the reference clock fr by 1/72 and 1/144 to generate a fourth high-frequency signal f₄ which has the frequencies 5 [MHz] and 2.5 [MHz].

That is, when a frequency of the output signal fₒᵤₜ is 365 [MHz], a frequency of the fourth high-frequency signal f₄ is set to 5 [MHz]. On the other hand, when a frequency of the output signal fₒᵤₜ is 362.5 [MHz], a frequency of the fourth high-frequency signal f₄ is set to 2.5 [MHz]. As a result, even if a frequency of any one of the channels is generated at the VCO 14, an output frequency of the first output mixer 2700 can be maintained at 360 [MHz].

In the case of a frequency divider which cannot execute the aforementioned fractional dividing, a frequency of the reference clock fr becomes 5 [MHz] when the VCO 14 oscillates at one of the frequencies 5795 [MHz], 5805 [MHz], 5835 [MHz], and 5845 [MHz]. On the other hand, the frequency divider 2h of the third modification of the third embodiment can be used even if a frequency of the reference clock fr is high. Moreover, even if a ratio between a frequency of the reference clock fr and a frequency of the oscillation signal f_{vco} generated by the VCO 14 is not an integer, no high-speed switching is necessary. Thus, noise which occurs in the fractional frequency divider of the switch system is not generated.

### Fourth Modification of Third Embodiment

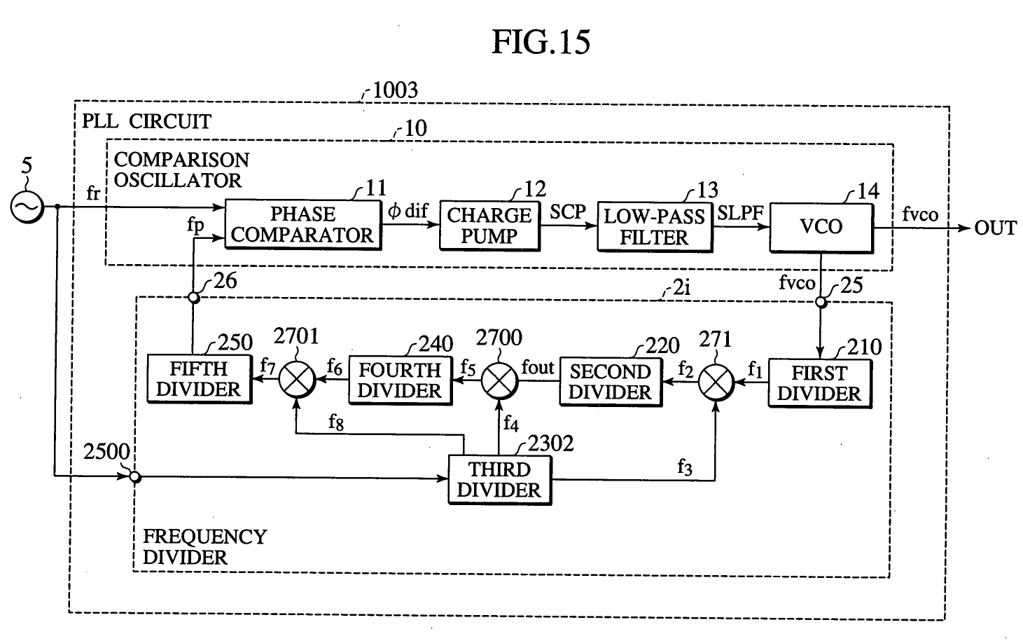

As shown in FIG. 15, a frequency divider 2i of a fourth modification of the third embodiment of the present invention may include, in addition to the components of FIG. 14, a fourth divider 240 connected to the first output mixer 2700, a second output mixer 2701 connected to the fourth divider 240, and a fifth divider 250 connected between the second output mixer 2701 and the output terminal 26. The second output mixer 2701 is constituted similar to, e.g., that of FIG. 6.

The fourth divider 240 divides a fifth high-frequency signal f₅ from the first output mixer 2700 to generate a sixth high-frequency signal f₆. Here, when a frequency of the fifth high-frequency signal f₅ is 360 [MHz], and a division ratio of the fourth divider 240 is 1/4, the frequency of the sixth high-frequency signal f₆ is 90 [MHz].

Further, the fifth divider 250 divides a seventh high-frequency signal f₇ from the second output mixer 2701. The third divider 2302 supplies an eighth high-frequency signal f₈ to the second output mixer 2701. When a frequency of the eighth high-frequency signal f₈ is 10 [MHz], the frequency of the seventh high-frequency signal f₇ is 80 [MHz]. When a division ratio of the fifth divider 250 is 1/2, an output frequency of the fifth divider 250 is 40 [MHz].

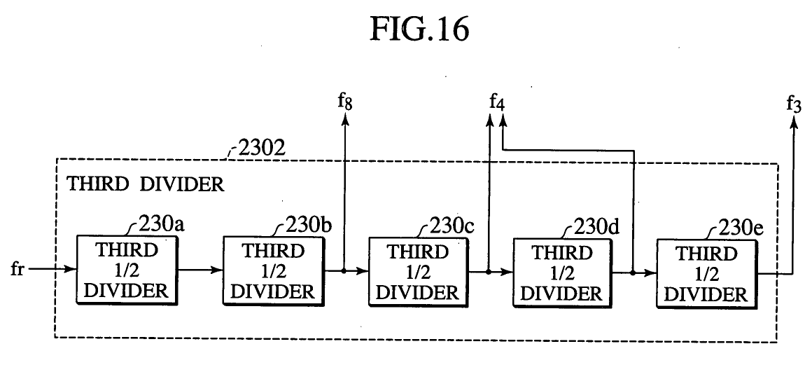

Thus, the third divider 2302 generates frequencies of 1.25 [MHz], 2.5 [MHz], 5 [MHz], and 10 [MHz]. When a frequency of the reference clock fr is 40 [MHz], the third divider 2302 is constituted similar to, e.g., that of FIG. 16 to be able to generate frequencies of 1.25 [MHz], 2.5 [MHz], 5 [MHz], and 10 [MHz]. The third divider 2302 shown in FIG. 16 includes third ½ dividers 230a to 230e which are cascade-connected at five stages. The third ½ divider 230b of the second stage generates an eighth high-frequency signal f₈, and supplies signal f₈ to the second output mixer 2701 shown in FIG. 15. The third ½ dividers 230c and 230d constituting the third and fourth stages generate a fourth high-frequency signal f₄, and supplies signal f₄ to the first output mixer 2700. The third ½ divider 230e of the last stage generates a third high-frequency signal f₃, and supplies signal f₃ to the mixer 271.

### Other Embodiments

Various modifications will become possible for those skilled in the art after receiving the teachings of the present disclosure without departing from the scope thereof.

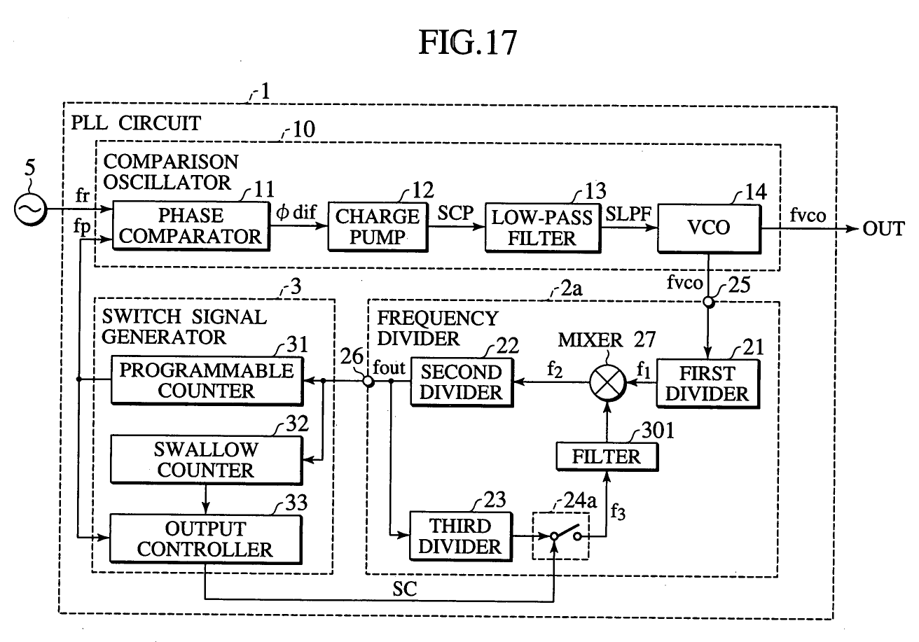

As a frequency divider 2j of the other embodiment, as shown in FIG. 17, a filter 301 may be connected between a switch circuit 24a and a mixer 27. As a result, it is possible to remove very small noise generated by the switch circuit 24a. Similarly, a filter can be provided in the frequency divider 2b of the modification of the first embodiment. In this case, the filter is connected between the switch circuit 24b and the third divider 23 shown in FIG. 3.

According to the aforementioned first to third embodiments, the reference clock fr supplied to the PLL circuits 1, 100, and 1000 to 1003 is generated by the reference clock generator 5. However, the reference clock fr does not always need to generated by the reference clock generator 5. That is, the PLL circuits 1, 100, 1000 of the first to third embodiments can be used for various purposes in addition to use as frequency synthesizers.

The aforementioned second embodiment has been described by way of example in which the switch circuit 24a is provided between the third divider 230 and the mixer 270. However, the switch circuit 24b may be provided between the output terminal 26 and the third divider 230 as in the case of the frequency divider 2b of the modification of the first embodiment. Moreover, according to the second embodiment, the ½ divider of the master/slave system is used as the ½ divider. However, the invention is not limited to the ½ divider of the master/slave system. For example, a ½ divider which uses LC resonance can be used.

Further, as the modification of the second embodiment, the frequency divider 2d has been described, which is constituted in such a manner that the switch signal SC is supplied to the third ½ divider 330 of the first stage of the third divider 231. However, the switch signal SC may be supplied to any one of the third ½ dividers 230a to 230n.

Furthermore, according to the first and second embodiments, nMOS transistors are used for the switch circuits 24a, 24b, the first to fourth current source transistors Tr9, Tr10, Tr11, Tr12, and the first to eighth differential transistors Tr1, Tr2, Tr3, Tr4, Tr5, Tr6, Tr7, Tr8. Needless to say, however, various transistors can be used such as bipolar junction transistors (BJT), junction field effect transistors (JFET), metal-semiconductor field effect transistors (MESFET), static induction transistors (SIT), and high electron mobility transistors (HEMT). Note that the invention is not limited to the nMOS transistors, but p-channel metal-oxide-semiconductor (PMOS) transistors may be used.

The aforementioned third embodiment has been described by way of example in which the first exchange circuit 85 and the second exchange circuit 86 are provided in the mixer 271. However, disposition of an exchange circuit between the first divider 251 and the mixer 271 enables the mixer 271 to execute addition processing. Alternatively, an exchange circuit may be provided between the third divider 253 and the mixer 271.

According to the modification of the third embodiment, the filter 300 is connected between the third divider 253 and the mixer 271 to remove the higher harmonic wave component of the third high-frequency signal f₃. However, the higher harmonic wave component of the third high-frequency signal f₃ can be removed by slowing down an operating speed of the third divider 253 to slow down rising and falling speeds of a waveform of the third high-frequency signal f₃, i.e., slowing down a time change in voltage. Specifically, a transistor load capacity and a driving resistance in the third divider 253 only need to be adjusted. A time change of rising and falling of the waveform of the third high-frequency signal f₃ is decided in inversion proportion to a product of the transistor load capacitance and the driving resistance, i.e., a time constant. Thus, it is only necessary to use a method for adding a capacity to the third divider 253, extending a gate length of the internal transistor, or adding a current limiter or the like.

The aforementioned first to third embodiments have been described by way of example in which gilbert cell mixers are used for the mixers 27, 270, 271. Needless to say, however, mixers different from the gilbert cell mixers may be used. Moreover, the polyphase filter is used for the filter 300 according to the modification of the third embodiment. However, any filter which removes higher harmonic waves can be used for the filter 300.

Furthermore, the third and fourth modifications of the third embodiment have been described by way of example in which the PLL circuits 1002 and 1003 are applied to the ETC system. However, frequencies of the reference clock fr and the oscillation signal f_{vco} can be optionally changed by changing the number of dividers, the division ratios thereof, and the mixer circuitry.

### CROSS REFERENCE TO RELATED APPLICATIONS

This application is based upon and claims the benefit of priority from the prior Japanese Patent Applications No. P2003-007591 filed on Jan. 15, 2003, and No. P2003-389652 filed on Nov. 19, 2003; the entire contents of which are incorporated herein by reference.

1. A frequency divider comprising:
a first divider configured to divide an input signal, and to generate a first high-frequency signal;
a second divider configured to divide a second high-frequency signal, and to generate an output signal;
a third divider configured to generate a third high-frequency signal; and
a mixer configured to execute arithmetic processing for the first and third high-frequency signals, and to generate the second high-frequency signal.

2. The frequency divider of claim 1, wherein the third divider divides the output signal and generates the third high frequency signal.

3. The frequency divider of claim 2, wherein the mixer executes subtraction processing as the arithmetic processing for the first high-frequency signal and the third high-frequency signal.

4. The frequency divider of claim 2, wherein the mixer executes subtraction processing or addition processing as the arithmetic processing for the first high-frequency signal and the third high-frequency signal.

5. The frequency divider of claim 2, wherein the first, second, and third dividers respectively comprise a plurality of stages of cascade-connected first ½ dividers, second ½ dividers, and third ½ dividers.

6. The frequency divider of claim 5, wherein a switch signal stopping operation of the third divider is supplied to the third ½ divider.

7. The frequency divider of claim 2, wherein division ratios of the second divider and the third divider are variable.

8. The frequency divider of claim 2, further comprising a filter connected between the third divider and the mixer.

9. The frequency divider of claim 2, further comprising a switch circuit connected between the third divider and the mixer.

10. The frequency divider of claim 2, further comprising a switch circuit connected between the second divider and the third divider.

11. The frequency divider of claim 1, wherein the third divider divides an external reference clock, and generates the third high frequency signal.

12. The frequency divider of claim 11, wherein the first, second, and third dividers respectively comprise a plurality of stages of cascade-connected first ½ dividers, second ½ dividers, and third ½ dividers.

13. The frequency divider of claim 11, wherein the mixer executes subtraction processing or addition processing as the arithmetic processing for the first high-frequency signal and the third high-frequency signal.

14. The frequency divider of claim 11, wherein division ratios of the second divider and the third divider are variable.

15. The frequency divider of claim 11, wherein the third divider further generates a fourth high-frequency signal.

16. The frequency divider of claim 15, further comprising a first output mixer configured to execute arithmetic processing for the output signal and the fourth high-frequency signal.

17. A semiconductor integrated circuit comprising:
a first divider integrated on a semiconductor chip and configured to divide an input signal, and to generate a first high-frequency signal;
a second divider integrated on the semiconductor chip and configured to divide a second high-frequency signal, and to generate an output signal;
a third divider integrated on the semiconductor chip and configured to generate a third high-frequency signal; and
a mixer integrated on the semiconductor chip and configured to execute arithmetic processing for the first and third high-frequency signals, and to generate the second high-frequency signal.

18. A phase locked loop circuit comprising:
a comparison oscillator configured to generate an oscillation signal having a frequency corresponding to a phase difference between a reference clock and a comparison clock; and
a frequency divider configured to divide the oscillation signal to generate a first high-frequency signal, and to divide a second high-frequency signal, and to generate a third high-frequency signal, and to execute arithmetic processing for the first and third high-frequency signals and to generate the second high-frequency signal.

19. The phase locked loop circuit of claim 18, wherein the frequency divider comprises:
a first divider configured to generate the first high-frequency signal;
a second divider configured to divide the second high-frequency signal, and to generate an output signal;
a third divider configured to divide the output signal, and to generate the third high-frequency signal; and
a mixer configured to generate the second high-frequency signal.

20. The phase locked loop circuit of claim 18, wherein the frequency divider comprises:
a first divider configured to generate the first high-frequency signal;
a second divider configured to divide the second high-frequency signal, and to generate an output signal;
a third divider configured to divide the reference clock, and to generate the third high-frequency signal; and
a mixer configured to generate the second high-frequency signal.
